(19) United States
(12) Patent Application Publication
(10) Pub. No.: US 2015/0214505 A1
(43) Pub. Date: Jul. 30, 2015

(54) AMOLED DISPLAY PANEL, METHOD OF FABRICATING FILM LAYER AND DISPLAY APPARATUS

(71) Applicants: Shanghai Tianma AM-OLED Co., Ltd., Shanghai (CN); Tianma Micro-Electronics Co., Ltd., Shenzhen (CN)

(72) Inventors: Zhiyong Xiong, Shanghai (CN); Dong Qian, Shanghai (CN)

(73) Assignees: Shanghai Tianma AM-OLED Co., Ltd., Shanghai (CN); Tianma Micro-Electronics Co., Ltd., Shenzhen (CN)

(21) Appl. No.: 14/286,773

(22) Filed: May 23, 2014

(30) Foreign Application Priority Data
Jan. 27, 2014 (CN) 201410040747.X

(51) Int. Cl. H01L 51/52; H01L 51/56; H01L 27/32

(52) U.S. Cl. CPC H01L 51/5271; H01L 27/3211; H01L 27/3244; H01L 51/56; H01L 2227/323

(57) ABSTRACT

An Active Matrix Organic Light Emitting Diode (AMOLED) display panel is disclosed. The display panel includes a substrate, an anode layer on the substrate, a hole transport layer on the anode layer, an illuminating layer on the hole transport layer, an electron transport layer on the illuminating layer, a cathode layer on the electron transport layer, and a cathode protection layer on the cathode layer. In addition, at least one of the hole transport layer and the cathode protection layer includes a film having a uniform thickness.

### CROSS-REFERENCES TO RELATED APPLICATIONS

The present application claims priority to Chinese patent application No. 201410040747.X, entitled “AMOLED display panel, method of fabricating film layer and display apparatus”, filed with the State Intellectual Property Office of People's Republic of China on Jan. 27, 2014, the content of which is incorporated herein by reference in its entirety.

### TECHNICAL FIELD

The present invention relates to the field of display technologies and particularly to an AMOLED display panel, a method of fabricating film layer, and a display apparatus.

### BACKGROUND OF THE INVENTION

Active Matrix Organic Light Emitting Diodes (AMOLEDs) have a high response speed, a high contrast, a wide angle of view, an excellent display effect, low power consumption, and other advantages in comparison with a traditional liquid crystal panel. The AMOLEDs have the characteristic of self-illuminating without using any backlight board and thus can be made lighter and thinner than a Thin Film Transistor Liquid Crystal Display (TFT-LCD), and the AMOLEDs without using any backlight board can save the cost of a backlight board accounting for 30 to 40 percentages of the cost of the TFT-LCD.

The self-illuminating AMOLEDs may come with different pixels aging differently in the course of aging, which may result in different brightness and potentially lead to an afterimage on a display screen, wherein the brightness of a blue sub-pixel may decay faster than the brightness of a red sub-pixel and a green sub-pixel. In the prior art, in order to address the afterimage appearing on the AMOLED display screen after being used for a period of time, a typical practice is to lower the current density of an illuminating layer of blue sub-pixels 13, i.e., an illuminating layer of B pixel sub-pixel 13, by increasing the area thereof to thereby compensate the decay in brightness of the blue sub-pixels, as illustrated in FIG. 1, where the area of the illuminating layer of blue sub-pixels 13 is set larger than the area of an illuminating layer of red sub-pixels 11, i.e., an illuminating layer of R pixels 11, and larger than the area of an illuminating layer of green sub-pixels 12, i.e., an illuminating layer of G pixels 12, but the increase in area of the illuminating layer of blue sub-pixels may result in a drop in overall resolution of the AMOLED display screen.

In summary, the AMOLED display screen in the prior art may suffer from a low overall resolution and consequently a poor overall quality thereof.

### BRIEF SUMMARY OF THE INVENTION

One inventive aspect is an Active Matrix Organic Light Emitting Diode (AMOLED) display panel. The display panel includes a substrate, an anode layer on the substrate, a hole transport layer on the anode layer, an illuminating layer on the hole transport layer, an electron transport layer on the illuminating layer, a cathode layer on the electron transport layer, and a cathode protection layer on the cathode layer. In addition, at least one of the hole transport layer and the cathode protection layer includes a film having a uniform thickness.

Another inventive aspect is an AMOLED display apparatus including an AMOLED display panel. The AMOLED display panel includes a substrate, an anode layer on the substrate, a hole transport layer on the anode layer, an illuminating layer on the hole transport layer, an electron transport layer on the illuminating layer, a cathode layer on the electron transport layer, and a cathode protection layer on the cathode layer. In addition, at least one of the hole transport layer and the cathode protection layer includes a film having a uniform thickness.

Another inventive aspect is a method of fabricating an AMOLED film layer. The method includes fabricating an anode layer and a hole transport layer on a substrate in sequence. The method also includes fabricating an illuminating layer, an electron transport layer, a cathode layer, and a cathode protection layer on the hole transport layer in sequence. In addition, at least one of the hole transport layer and the cathode protection layer includes a film having a uniform thickness.

### BRIEF DESCRIPTION OF THE DRAWINGS

FIG. 1 is a schematic diagram of arrangement of pixels in an AMOLED display screen in the prior art;

FIG. 2 is a schematic structural diagram of an AMOLED display panel according to an embodiment of the invention;

FIG. 3 is a diagram showing a relationship between the thickness of a cathode protection layer and the illumination intensity of an illuminating layer in an AMOLED display panel according to an embodiment of the invention;

FIG. 4 is a schematic structural diagram of an AMOLED display panel in the prior art;

FIG. 5 is a schematic diagram of a vapor-deposition mask used in fabrication of a cathode protection layer in the AMOLED display panel in FIG. 4;

FIG. 6 is a schematic diagram of a vapor-deposition mask used in fabrication of a cathode protection layer in an AMOLED display panel according to an embodiment of the invention;

FIG. 7 is a schematic structural diagram of an AMOLED display panel according to an embodiment of the invention;

FIG. 8 is a schematic structural diagram of an AMOLED display panel according to an embodiment of the invention;

FIG. 9 is a schematic structural diagram of an AMOLED display panel according to an embodiment of the invention;

FIG. 10 is a schematic structural diagram of an AMOLED display apparatus according to an embodiment of the invention.

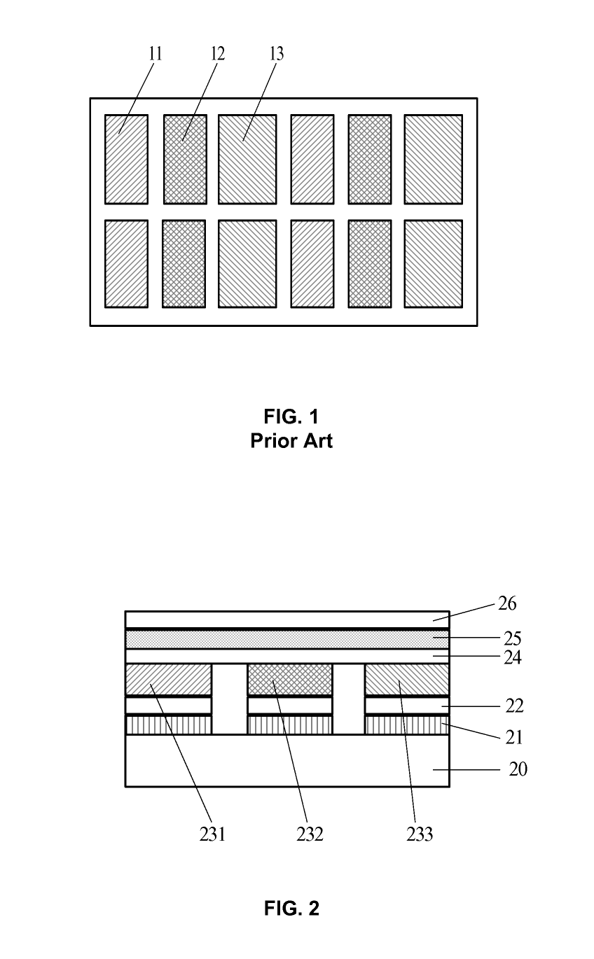

### DETAILED DESCRIPTION OF THE PREFERRED EMBODIMENTS

Embodiments of the invention provide an Active Matrix Organic Light Emitting Diode (AMOLED) display panel, an AMOLED display apparatus, and a method of fabricating an AMOLED film layer so as to improve the resolution of an AMOLED display screen, lower power consumption of the AMOLED display screen, simplify a process of manufacturing the AMOLED display screen, improve matching of brightness decays of the AMOLED display screen, and improve the overall quality of the AMOLED display screen.

Technical solutions according to embodiments of the invention will be described below in details.

As illustrated in FIG. 2, an AMOLED display panel according to a particular embodiment of the invention includes a substrate 20, an anode layer 21, a hole transport layer 22, an illuminating layer, an electron transport layer 24, a cathode layer 25, and a cathode protection layer 26, wherein the cathode protection layer 26 is a film layer with a uniform thickness and being consistent throughout the film layer, and the illuminating layer includes an illuminating layer of R pixels 231, an illuminating layer of G pixels 232, and an illuminating layer of B pixels 233, wherein the cathode protection layer 26 may be made of Alq3 (8-Hydroxyquinoline aluminum) or other organic materials, or the cathode protection layer 26 may be made of CaO, SiO2 or other ceramic materials.

A method of fabricating an AMOLED film layer according to an embodiment of the invention includes: fabricating an anode layer 21 and a hole transport layer 22 on a substrate 20 in sequence; and fabricating an illuminating layer, an electron transport layer 24, a cathode layer 25, and a cathode protection layer 26 on the hole transport layer 22 in sequence, wherein the cathode protection layer 26 is a film layer with a uniform thickness and being consistent throughout the film layer, and the illuminating layer includes an illuminating layer of R pixels 231, an illuminating layer of G pixels 232, and an illuminating layer of B pixels 233.

In a particular embodiment of the invention, the thickness of the cathode protection layer 26 is selected so that the thickness of the cathode protection layer 26 enables an optimum optical coupling efficiency for the illuminating layer of B pixels 233. Since there are different illumination wavelengths for the illuminating layer of R pixels 231, the illuminating layer of G pixels 232, and the illuminating layer of B pixels 233, there are ordinary optical coupling efficiencies for the illuminating layer of R pixels 231 and the illuminating layer of G pixels 232 when the thickness of the cathode protection layer 26 enables an optimum optical coupling efficiency for the illuminating layer of B pixels 233.

Specifically Table 1 depicts a relationship between the thickness of a cathode protection layer and the illumination intensities of respective illuminating layers of sub-pixels in an AMOLED display panel according to an embodiment of the invention.

TABLE 1

| | | Illumination | |
|---|---|---|---|
| | Illumination | intensity of | |
| Thickness | intensity of | illuminating | Illumination intensity |
| of cathode | illuminating layer | layer | of illuminating layer |
| protection layer | of B pixels | of G pixels | of R pixels |
| 55 | 11 | 160 | 30 |
| 65 | 13 | 140 | 30 |
| 75 | 15.1 | 120 | 40 |
| 85 | 16.6 | 100 | 30 |
| 95 | 17.2 | 100 | 30 |
| 105 | 16.8 | 100 | 30 |
| 115 | 15.6 | 100 | 20 |
| 125 | 13.8 | 120 | 20 |
| 135 | 11.9 | 140 | 20 |
| 145 | 10.1 | 165 | 15 |

As depicted in Table 1, when the thickness of the cathode protection layer 26 is 55 nm, the Illumination intensity of the illuminating layer of B pixels 233 is 11 candelas, the Illumination intensity of the illuminating layer of G pixels 232 is 160 candelas, and the Illumination intensity of the illuminating layer of R pixels 231 is 30 candelas; when the thickness of the cathode protection layer 26 is 65 nm, the Illumination intensity of the illuminating layer of B pixels 233 is 13 candelas, the Illumination intensity of the illuminating layer of G pixels 232 is 140 candelas, and the Illumination intensity of the illuminating layer of R pixels 231 is 30 candelas; when the thickness of the cathode protection layer 26 is 75 nm, the Illumination intensity of the illuminating layer of B pixels 233 is 15.1 candelas, the Illumination intensity of the illuminating layer of G pixels 232 is 120 candelas, and the Illumination intensity of the illuminating layer of R pixels 231 is 40 candelas; when the thickness of the cathode protection layer 26 is 85 nm, the Illumination intensity of the illuminating layer of B pixels 233 is 16.6 candelas, the Illumination intensity of the illuminating layer of G pixels 232 is 100 candelas, and the Illumination intensity of the illuminating layer of R pixels 231 is 30 candelas; when the thickness of the cathode protection layer 26 is 95 nm, the Illumination intensity of the illuminating layer of B pixels 233 is 17.2 candelas, the Illumination intensity of the illuminating layer of G pixels 232 is 100 candelas, and the Illumination intensity of the illuminating layer of R pixels 231 is 30 candelas; when the thickness of the cathode protection layer 26 is 105 nm, the Illumination intensity of the illuminating layer of B pixels 233 is 16.8 candelas, the Illumination intensity of the illuminating layer of G pixels 232 is 100 candelas, and the Illumination intensity of the illuminating layer of R pixels 231 is 30 candelas; when the thickness of the cathode protection layer 26 is 115 nm, the Illumination intensity of the illuminating layer of B pixels 233 is 15.6 candelas, the Illumination intensity of the illuminating layer of G pixels 232 is 100 candelas, and the Illumination intensity of the illuminating layer of R pixels 231 is 20 candelas; when the thickness of the cathode protection layer 26 is 125 nm, the Illumination intensity of the illuminating layer of B pixels 233 is 13.8 candelas, the Illumination intensity of the illuminating layer of G pixels 232 is 120 candelas, and the Illumination intensity of the illuminating layer of R pixels 231 is 20 candelas; when the thickness of the cathode protection layer 26 is 135 nm, the Illumination intensity of the illuminating layer of B pixels 233 is 11.9 candelas, the Illumination intensity of the illuminating layer of G pixels 232 is 140 candelas, and the Illumination intensity of the illuminating layer of R pixels 231 is 20 candelas; and when the thickness of the cathode protection layer 26 is 145 nm, the Illumination intensity of the illuminating layer of B pixels 233 is 10.1 candelas, the Illumination intensity of the illuminating layer of G pixels 232 is 165 candelas, and the Illumination intensity of the illuminating layer of R pixels 231 is 15 candelas.

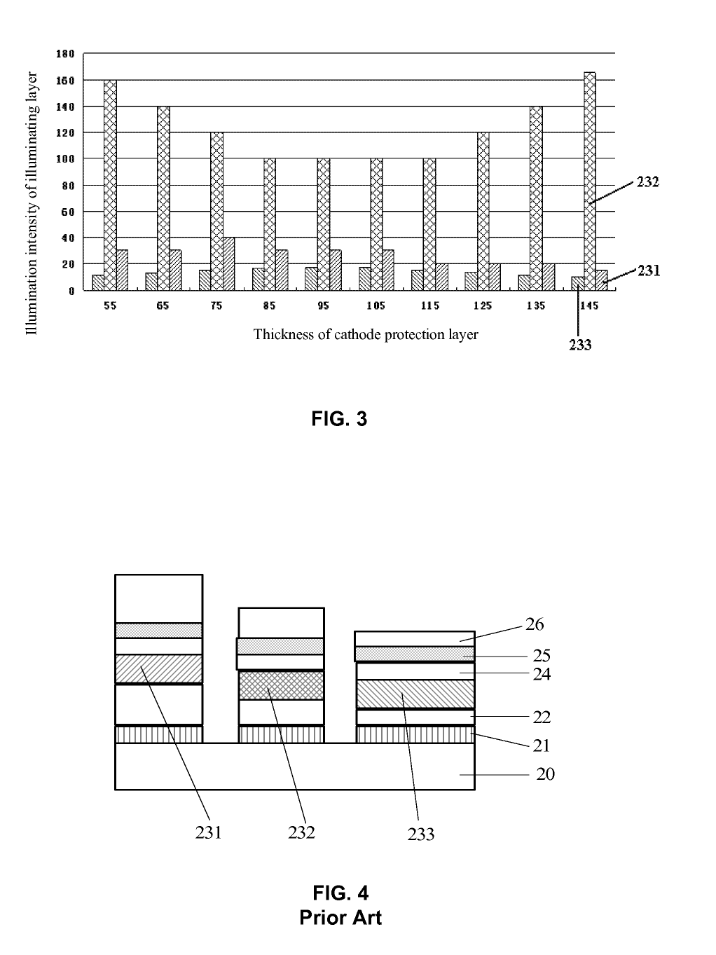

FIG. 3 illustrates a diagram showing a relationship between the thickness of a cathode protection layer and the illumination intensity of an illuminating layer, wherein 231 represents the Illumination intensity of the illuminating layer of R pixels, 232 represents the Illumination intensity of the illuminating layer of G pixels, and 233 represents the Illumination intensity of the illuminating layer of B pixels. As can be seen from both table 1 and FIG. 3, the thickness of the cathode protection layer is 95 nm when there is an optimum optical coupling efficiency for the illuminating layer of B pixels 233; the thickness of the cathode protection layer is 55 nm or 145 nm when there is an optimum optical coupling efficiency for the illuminating layer of G pixels 232; and the thickness of the cathode protection layer is 75 nm when there is an optimum optical coupling efficiency for the illuminating layer of R pixels 231. The thickness of the cathode protection layer in a particular embodiment of the invention is selected as 95 nm to ensure an optimum optical coupling efficiency for the illuminating layer of B pixels 233 while there are ordinary optimum optical coupling efficiencies for the illuminating layer of R pixels 231 and the illuminating layer of G pixels 232.

Preferably in a practical manufacturing process, with reference to both Table 1 and FIG. 3, there is an optimum thickness range of the cathode protection layer in a particular embodiment of the invention, which is 75 nm to 115 nm. If the thickness of the cathode protection layer is further increased, then the illumination intensity of the illuminating layer of R pixels, the illumination intensity of the illuminating layer of G pixels, and the illumination intensity of the illuminating layer of B pixels will vary periodically across their peaks and valleys. As can be seen from Table 1, the thickness of the cathode protection layer varies from 55 nm to 135 nm in a periodicity, but the thickness range of the cathode protection layer in a particular embodiment of the invention will not be limited to 75 nm to 115 nm but can be extended periodically dependent upon a practical manufacturing process.

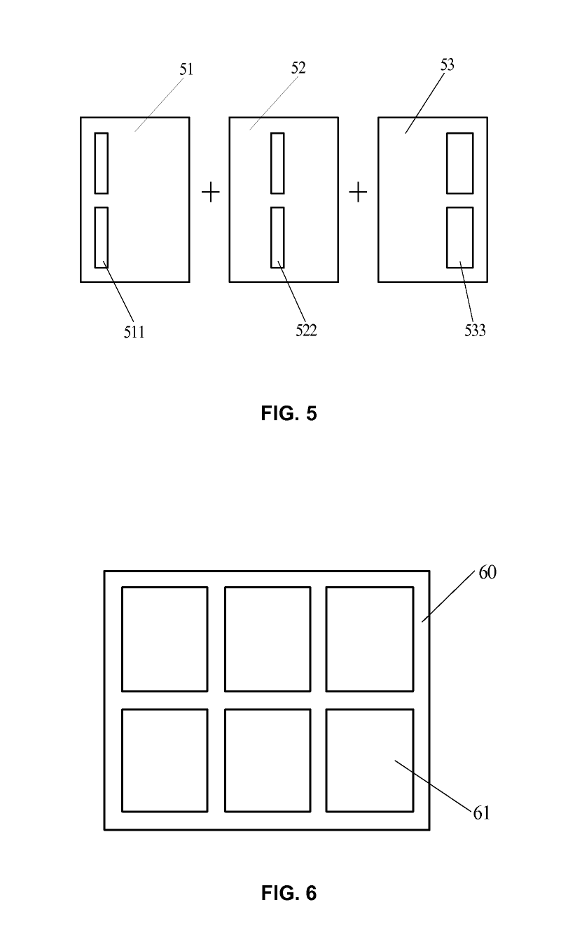

As illustrated in FIG. 4, the thickness of a cathode protection layer 26 in the prior art is not uniform, and the cathode protection layer 26 is an inconsistent and intermittent film layer. In the prior art, the area of the illuminating layer of B pixels 233 is larger than the area of the illuminating layer of R pixels 231 and the area of the illuminating layer of G pixels 232. The cathode protection layer has to be fabricated from three vapor-deposition masks 51, 52, and 53, as illustrated in FIG. 5, wherein the cathode protection layer on the illuminating layer of R pixels is fabricated from the vapor-deposition mask 51, the vapor-deposition mask 51 includes a plurality of openings 511, and the openings 511 are of the same order of magnitude as the R pixels; the cathode protection layer on the illuminating layer of G pixels is fabricated from the vapor-deposition mask 52, the vapor-deposition mask 52 includes a plurality of openings 522, and the openings 522 are of the same order of magnitude as the G pixels; and the cathode protection layer on the illuminating layer of B pixels is fabricated from the vapor-deposition mask 53, the vapor-deposition mask 53 includes a plurality of openings 533, and the openings 533 are of the same order of magnitude as the B pixels. It may be rather difficult to control processes of both fabricating and accessing a mask itself in the prior art, and fabrication of multiple masks may also complicate the fabrication process.

The cathode protection layer is fabricated in an embodiment of the invention by depositing the cathode protection layer on the cathode layer using a vapor-deposition mask, openings of the vapor-deposition mask have the same size as a display area of the panel, as illustrated in FIG. 6, where a vapor-deposition mask 60 includes a plurality of openings 61 in the same size as a display area of the display panel. Thus the cathode protection layer is fabricated in the embodiment of the invention merely from one mask in a simplified fabrication process, and openings of the mask have the same size as the display area of the panel.

The AMOLED display panel in the prior art and the AMOLED display panel according to the embodiment of the invention were tested resulting in experimental data as depicted in Table 2.

TABLE 2

| Item | Prior Art | Embodiment of the Invention |
|---|---|---|
| Brightness in red (cd/m²) | 62 | 62 |
| Brightness in green (cd/m²) | 187 | 187 |
| Brightness in blue (cd/m²) | 51 | 51 |
| Brightness in white (cd/m²) | 300 | 300 |
| Chroma in red (x, y) | (0.65, 0.33) | (0.65, 0.33) |
| Chroma in green (x, y) | (0.33, 0.65) | (0.33, 0.65) |
| Chroma in blue (x, y) | (0.15, 0.12) | (0.15, 0.12) |
| Chroma in white (x, y) | (0.33, 0.33) | (0.33, 0.33) |
| Efficiency in red (cd/A) | 15 | 15 |
| Efficiency in green (cd/A) | 30 | 30 |
| Efficiency in blue (cd/A) | 5 | 10 |
| Current in red (mA) | 41 | 41 |
| Current in green (mA) | 62 | 62 |
| Current in blue (mA) | 25.5 | 12.8 |
| Area in red (mm²) | 0.01 | 0.01 |
| Area in green (mm²) | 0.01 | 0.01 |
| Area in blue (mm²) | 0.02 | 0.01 |
| Lifetime in red (hours) | 50 | 50 |
| Lifetime in green (hours) | 50 | 50 |
| Lifetime in blue (hours) | 50 | 50 |

As can be seen from Table 2, the brightness and the chroma in red, green, and blue, i.e., white balance, was maintained in the AMOLED display panel according to the embodiment of the invention; and the efficiency in blue was doubled and the drive current in blue was halved, that is, the efficiency in blue was improved and the current in blue was lowered, to achieve the same brightness and thus lower power consumption in the AMOLED display panel according to the embodiment of the invention as compared with the prior art; and the area in blue was halved and thus the resolution was improved in the AMOLED display panel according to the embodiment of the invention as compared with the prior art; and there were still consistent lifetimes in red, green, and blue despite the changes in area and efficiency in blue in the AMOLED display panel according to the embodiment of the invention, so brightness decays were matched while lowering the power consumption and improving the resolution in the AMOLED display panel according to the embodiment of the invention.

Thus with the AMOLED display panel according to the embodiments of the invention, the resolution of an AMOLED display screen can be improved, power consumption of the AMOLED display screen can be lowered, matching of brightness decays of the AMOLED display screen can be improved, and a process of manufacturing the AMOLED display screen can be simplified, and thus the overall quality of the AMOLED display screen can be improved.

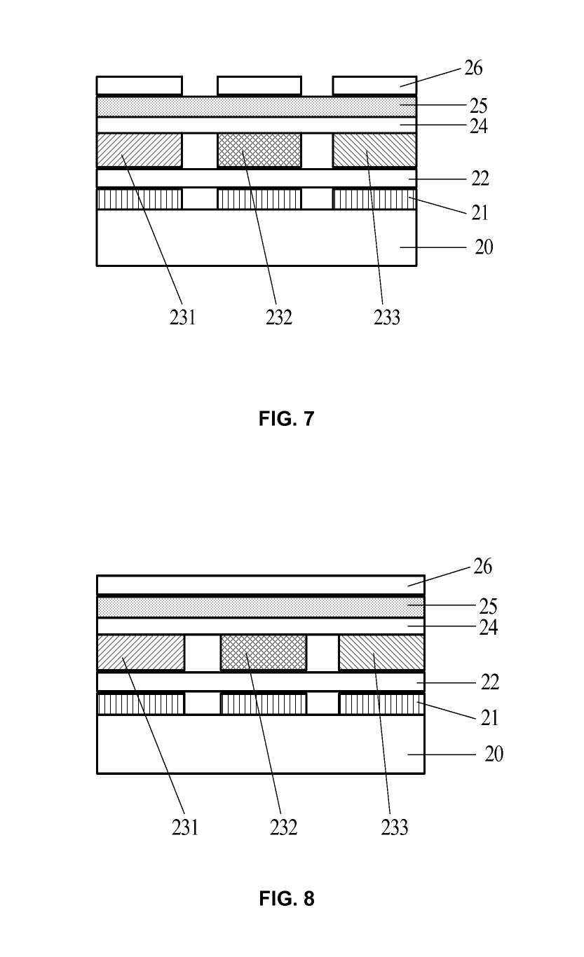

As illustrated in FIG. 7, an AMOLED display panel according to a particular embodiment of the invention includes a substrate 20, an anode layer 21, a hole transport layer 22, an illuminating layer, an electron transport layer 24, a cathode layer 25, and a cathode protection layer 26, wherein the hole transport layer 22 is a film layer with a uniform thickness and being consistent throughout the film layer, and the illuminating layer includes an illuminating layer of R pixels 231, an illuminating layer of G pixels 232, and an illuminating layer of B pixels 233.

A method of fabricating an AMOLED film layer according to the embodiment of the invention includes: fabricating an anode layer 21 and a hole transport layer 22 on a substrate 20 in sequence; and fabricating an illuminating layer, an electron transport layer 24, a cathode layer 25, and a cathode protection layer 26 on the hole transport layer 22 in sequence, wherein the hole transport layer 22 is a film layer with a uniform thickness and being consistent throughout the film layer, and the illuminating layer includes an illuminating layer of R pixels 231, an illuminating layer of G pixels 232, and an illuminating layer of B pixels 233.

The hole transport layer 22 in this embodiment is a film layer with a uniform thickness and being consistent throughout the film layer, and the thickness of the hole transport layer 22 is selected so that the thickness of the hole transport layer 22 enables an optimum optical coupling efficiency for the illuminating layer of B pixels 233 while there are ordinary optical coupling efficiencies for the illuminating layer of R pixels 231 and the illuminating layer of G pixels 232. When the thickness of the hole transport layer 22 in this embodiment is 37 nm, the Illumination intensity of the illuminating layer of B pixels 233 is 10.97 candelas, the Illumination intensity of the illuminating layer of G pixels 232 is 4.6 candelas, and the Illumination intensity of the illuminating layer of R pixels 231 is 3.7 candelas; when the thickness of the hole transport layer 22 is 85 nm, the Illumination intensity of the illuminating layer of G pixels 232 is 18.4 candelas, and the Illumination intensity of the illuminating layer of B pixels 233 is less than 10.97 candelas; and when the thickness of the hole transport layer 22 is 140 nm, the Illumination intensity of the illuminating layer of R pixels 231 is 10.4 candelas, and the Illumination intensity of the illuminating layer of B pixels 233 is less than 10.97 candelas, that is, when the thickness of the hole transport layer 22 is 37 nm, there is an optimum optical coupling efficiency for the illuminating layer of B pixels 233 while there are ordinary optical coupling efficiencies for the illuminating layer of R pixels 231 and the illuminating layer of G pixels 232, so the thickness of the hole transport layer 22 is selected as 37 nm in this embodiment.

Preferably the hole transport layer in this embodiment is fabricated by depositing the hole transport layer on the anode layer using a vapor-deposition mask, openings of the vapor-deposition mask have the same size as a display area of the panel. The hole transport layer is fabricated in the embodiment merely from one mask in a simplified fabrication process, and openings of the mask have the same size as the display area of the panel.

Both the AMOLED display panel according to this embodiment and the AMOLED display panel in the prior art were tested resulting in experimental data as depicted in Table 2. Thus with the AMOLED display panel according to this embodiment, the resolution of an AMOLED display screen can be improved, power consumption of the AMOLED display screen can be lowered, matching of brightness decays of the AMOLED display screen can be improved, and a process of manufacturing the AMOLED display screen can be simplified, and thus the overall quality of the AMOLED display screen can be improved.

As illustrated in FIG. 8, an AMOLED display panel according to a particular embodiment of the invention includes a substrate 20, an anode layer 21, a hole transport layer 22, an illuminating layer, an electron transport layer 24, a cathode layer 25, and a cathode protection layer 26, wherein the hole transport layer 22 and the cathode protection layer 26 are film layers with uniform thicknesses and being consistent throughout the film layers, and the illuminating layer includes an illuminating layer of R pixels 231, an illuminating layer of G pixels 232, and an illuminating layer of B pixels 233.

A method of fabricating the AMOLED film layer according to an embodiment of the invention includes: fabricating an anode layer 21 and a hole transport layer 22 on a substrate 20 in sequence; and fabricating an illuminating layer, an electron transport layer 24, a cathode layer 25, and a cathode protection layer 26 on the hole transport layer 22 in sequence, wherein the hole transport layer 22 and the cathode protection layer 26 are film layers with uniform thicknesses and being consistent throughout the film layers, and the illuminating layer includes an illuminating layer of R pixels 231, an illuminating layer of G pixels 232, and an illuminating layer of B pixels 233.

The thicknesses of the hole transport layer 22 and the cathode protection layer 26 in the AMOLED display panel according to the particular embodiment of the invention are selected as in any of the foregoing embodiments, so a repeated description thereof will be omitted here, and again both the AMOLED display panel prepared according to this embodiment and the AMOLED display panel in the prior art were tested resulting in experimental data as depicted in Table 2. Thus with the AMOLED display panel according to this embodiment, the resolution of an AMOLED display screen can be improved, power consumption of the AMOLED display screen can be lowered, matching of brightness decays of the AMOLED display screen can be improved, and a process of manufacturing the AMOLED display screen can be simplified, and thus the overall quality of the AMOLED display screen can be improved.

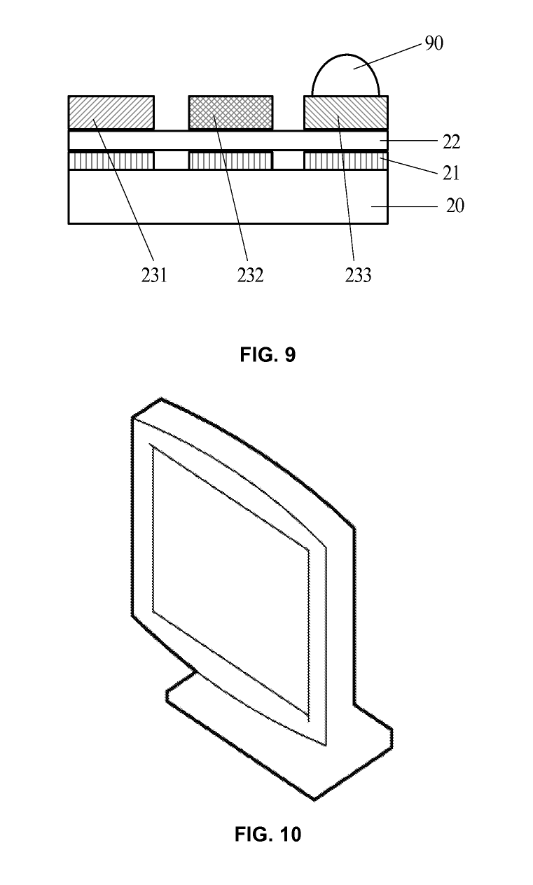

As illustrated in FIG. 9, there is illustrated an AMOLED display panel according to an embodiment of the invention where a micro-mirror 90 is fabricated on an illuminating layer of B sub-pixels 233 in an ink jetting process, and the remaining layers in the AMOLED display panel are fabricated as in any of the foregoing embodiments. Since light rays can be refracted and transmitted by the micro-mirror 90 resulting in higher out-coupling of the light rays, there will be an improved optical coupling efficiency for the illuminating layer of B sub-pixels 233 given the same drive current, that is, there will be a lower drive current required for the illuminating layer of B sub-pixels 233 for the same illumination.

Again both the AMOLED display panel prepared according to this embodiment and the AMOLED display panel in the prior art were tested resulting in experimental data as depicted in Table 2. Thus with the AMOLED display panel according to this embodiment the resolution of an AMOLED display screen can be improved, power consumption of the AMOLED display screen can be lowered, matching of brightness decays of the AMOLED display screen can be improved, and the overall quality of the AMOLED display screen can be improved.

A particular embodiment of the invention further provides an AMOLED display apparatus including the AMOLED display panel as described above, and the AMOLED display apparatus according to the particular embodiment of the invention can be a display, as illustrated in FIG. 10.

Evidently those skilled in the art can make various modifications and variations to the invention without departing from the essence and scope of the invention. Thus the invention is also intended to encompass these modifications and variations thereto so long as the modifications and variations come into the scope of the claims appended to the invention and their equivalents.

1. An Active Matrix Organic Light Emitting Diode (AMOLED) display panel comprising:
a substrate;
an anode layer on the substrate;
a hole transport layer on the anode layer;
an illuminating layer on the hole transport layer;
an electron transport layer on the illuminating layer;
a cathode layer on the electron transport layer; and
a cathode protection layer on the cathode layer,
wherein at least one of the hole transport layer and the cathode protection layer comprises a film having a uniform thickness, and
wherein the illuminating layer comprises:
a red illuminating layer,
a green illuminating, and
a blue illuminating layer,
wherein the red illuminating layer, the green illuminating layer, and the blue illuminating layer have the same area.

2. (canceled)

3. (canceled)

4. (canceled)

5. The AMOLED display panel of claim 1, wherein the illuminating layer further comprises a micro-mirror arranged on the blue illuminating layer.

6. The AMOLED display panel of claim 1, wherein a thickness of the cathode protection layer is between about 75 nm and about 115 nm.

7. An AMOLED display apparatus comprising an AMOLED display panel, wherein the AMOLED display panel comprises:
a substrate;
an anode layer on the substrate;
a hole transport layer on the anode layer;
an illuminating layer on the hole transport layer;
an electron transport layer on the illuminating layer;
a cathode layer on the electron transport layer; and
a cathode protection layer on the cathode layer,
wherein at least one of the hole transport layer and the cathode protection layer comprises a film having a uniform thickness, and
wherein the illuminating layer comprises:
a red illuminating layer,
a green illuminating, and
a blue illuminating layer,
wherein the red illuminating layer, the green illuminating layer, and the blue illuminating layer have the same area.

8. (canceled)

9. (canceled)

10. (canceled)

11. The AMOLED display apparatus of claim 7, wherein the illuminating layer further comprises a micro-mirror arranged on the blue illuminating layer.

12. The AMOLED display apparatus of claim 7, wherein a thickness of the cathode protection layer is between about 75 nm and 115 nm.

13. A method of fabricating an AMOLED film layer, the method comprising:
fabricating an anode layer and a hole transport layer on a substrate in sequence; and
fabricating an illuminating layer, an electron transport layer, a cathode layer, and a cathode protection layer on the hole transport layer in sequence,
wherein at least one of the hole transport layer and the cathode protection layer comprises a film having a uniform thickness, and
wherein the illuminating layer comprises:
a red illuminating layer,
a green illuminating, and
a blue illuminating layer,
wherein the red illuminating layer, the green illuminating layer, and the blue illuminating layer have the same area.

14. The method of claim 13, wherein the hole transport layer is fabricated by depositing the hole transport layer on the anode layer using a vapor-deposition mask, and wherein openings of the vapor-deposition mask have substantially the same size as a display area of a panel.

15. The method of claim 13, wherein the cathode protection layer is fabricated by depositing the cathode protection layer on the cathode layer using a vapor-deposition mask, and wherein openings of the vapor-deposition mask have substantially the same size as a display area of a panel.

16. (canceled)

17. (canceled)

18. (canceled)

19. The method of claim 13, further comprising:
fabricating a micro-mirror on the blue illuminating layer.
